(19) United States
(12) Patent Application Publication
(10) Pub. No.: US 2022/0043336 A1
(43) Pub. Date: Feb. 10, 2022

(54) PELLICLE FOR EUV LITHOGRAPHY, AND METHOD FOR MANUFACTURING THE SAME

(71) Applicant: S&S TECH Co., Ltd., Daegu-si (KR)

(72) Inventors: Cheol SHIN, Daegu-si (KR); Chang-Hun LEE, Daegu-si (KR); Ju-Hee HONG, Daegu-si (KR); Jong-Won YUN, Daegu-si (KR); Chul-Kyun PARK, Daegu-si (KR); Seung-Jo LEE, Daegu-si (KR); Ji-Hye KIM, Daegu-si (KR); Hae-Na LEE, Daegu-si (KR)

(73) Assignee: S&S TECH Co., Ltd., Daegu-si (KR)

(21) Appl. No.: 17/101,203

(22) Filed: Nov. 23, 2020

(30) Foreign Application Priority Data
Aug. 4, 2020 (KR) 10-2020-0097258

(51) Int. Cl. G03F 1/62; H01L 21/033

(52) U.S. Cl. CPC G03F 1/62; H01L 21/0337; H01L 21/0332

(57) ABSTRACT

A pellicle for extreme ultraviolet lithography includes a pellicle part configured to include a center layer and a reinforcing layer. The center layer essentially contains silicon (Si), and additionally contains at least one material of zirconium (Zr), zinc (Zn), ruthenium (Ru), and molybdenum (Mo). The reinforcing layer is made of a material containing at least one of silicon (Si), boron (B), zirconium (Zr), nitrogen (N), carbon (C), and oxygen (O). A thickness of the pellicle is minimized, and as a result, the pellicle has excellent mechanical, thermal, and chemical properties while maintaining high transmittance to EUV exposure light.

### CROSS-REFERENCE TO RELATED APPLICATION

This application is based on and claims priority under 35 U.S.C. § 119 to Korean Patent Application No. 10-2020-0097258, filed on Aug. 4, 2020, the disclosure of which is herein incorporated by reference in its entirety.

### BACKGROUND

### 1. Field

The disclosure relates to a pellicle for extreme ultraviolet (EUV) lithography, and a method for manufacturing the same, and more particularly, to a pellicle having high transmittance to EUV exposure light and capable of improving thermal and mechanical properties.

### 2. Discussion of Related Art

With the development of exposure technology called photo-lithography, high integration of semiconductor integrated circuits has been implemented. To form finer circuit patterns on a wafer, a resolution of exposure equipment, also called resolving power, needs to be increased. When a fine pattern beyond the limit of the resolution is transferred, light interference due to diffraction and scattering of light occurs, resulting in a problem that a distorted image different from an original mask pattern is transferred.

The currently commercialized exposure process performs the transfer process with the exposure equipment using an ArF wavelength of 193 nm to form the fine pattern on the wafer, but has limitations due to the diffraction and scattering of light with respect to the formation of the fine pattern of 50 nm or less. Therefore, various methods such as immersion lithography using a liquid medium that has a higher refractive index than air, double lithography that performs the exposure process twice, and phase shift technology that inverts a phase of light 180° to generate adjacent transmitted light and extinction interference, optical phase correction that corrects the phenomenon that a size of a design pattern becomes smaller or an end portion of the design pattern is rounded due to the interference and diffraction effects of light, and the like have been developed.

However, the exposure technology using the ArF wavelength has a problem in that it is difficult to implement a finer circuit line width of 32 nm or less, and production cost and process complexity are inevitably increased. Accordingly, EUV lithography technology using extreme ultraviolet (hereinafter referred to as EUV) light that uses, as a main exposure wavelength, a wavelength of 13.5 nm which is a very short wavelength compared to the wavelength of 193 nm is attracting attention as a next-generation process.

On the other hand, in the lithography process, a photomask is used as a disk for patterning, and a pattern on the photomask is transferred to a wafer. In this case, when impurities such as particles or foreign objects adhere on the photomask, exposure light may be absorbed or reflected due to the impurities and thus the pattern may be damaged, which may result in a decrease in performance or yield of a semiconductor device.

Accordingly, in order to prevent impurities from adhering on a surface of the photomask, a method for attaching a pellicle to a photomask is used. The pellicle is placed on the surface of the photomask, and even if impurities adhere on the pellicle, a focus matches the pattern of the photomask during the photolithography process, so the impurities on the pellicle are not transferred to the wafer surface due to the mismatch of the focus. In recent years, since the size of impurities that may affect the pattern damage has also decreased as a circuit line width becomes finer, the role of a pellicle for photomask protection is becoming more important. The pellicle needs to be basically configured in the form of a thin film with a thickness of 100 nm or less for smooth transmission of EUV exposure light, and mechanical reliability for vacuum environment and stage movement acceleration, excellent transmittance to EUV exposure light, and thermal stability capable of withstanding the long-term exposure process need to be satisfied, and constituent materials and structures are determined in consideration of these factors.

### SUMMARY

The disclosure is to provide a pellicle for extreme ultraviolet lithography having high transmittance to exposure light and excellent in thermal properties and mechanical strength, and a method for manufacturing the same.

According to an aspect of the disclosure, a pellicle for extreme ultraviolet lithography includes a pellicle part configured to include a center layer and a reinforcing layer. The center layer may essentially contain silicon (Si), and may additionally contain at least one material of zirconium (Zr), zinc (Zn), ruthenium (Ru), and molybdenum (Mo), or may be made of a compound which additionally contains at least one of nitrogen (N), carbon (C), and oxygen (O) added to the at least one material. The reinforcing layer may be made of a material containing at least one of silicon (Si), boron (B), zirconium (Zr), nitrogen (N), carbon (C), and oxygen (O).

The center layer may have a thickness of 100 nm or less.

The central layer may be surface-treated through ion implantation or a diffusion process that uses ion or gas of at least one material of boron (B), arsenic (As), antimony (Sb), nitrogen (N), carbon (C), oxygen (O), and hydrogen (H).

The reinforcing layer may have a thickness of 50 nm or less.

A capping layer having a single layer structure or a multilayer structure may be formed on at least one of upper and lower portions of the center layer.

The capping layer may be made of at least one material of silicon (Si), boron (B), zirconium (Zr), zinc (Zn), niobium (Nb), titanium (Ti), or nitrogen (N), or may be made of a compound which contains at least one material of nitrogen (N), carbon (C), and oxygen (O) added to the at least one material.

The capping layer may have a thickness of 50 nm or less.

According to the disclosure, by minimizing a thickness of pellicle, it is possible to provide a pellicle for extreme ultraviolet lithography having excellent mechanical, thermal, and chemical properties while maintaining a high transmittance to the EUV exposure light.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a cross-sectional view of a pellicle for extreme ultraviolet lithography according to a first embodiment of the disclosure.

FIGS. 2 to 8 are diagrams sequentially illustrating a manufacturing process of the pellicle for extreme ultraviolet lithography of FIG. 1.

FIG. 9 is a cross-sectional view illustrating a pellicle for extreme ultraviolet lithography according to a second embodiment of the disclosure.

### DETAILED DESCRIPTION

Hereinafter, the disclosure will be described in detail with reference to the accompanying drawings.

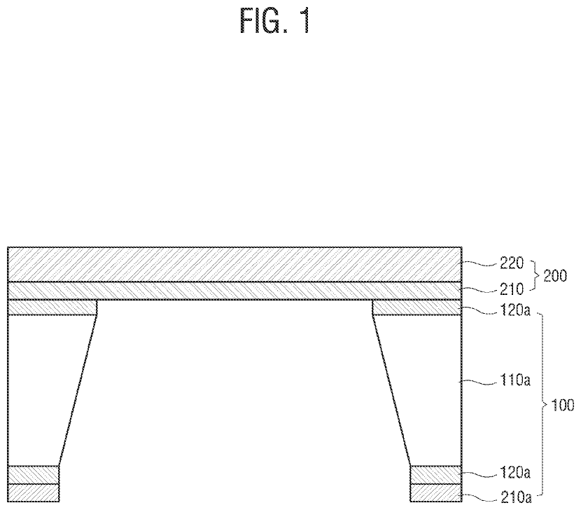

FIG. 1 is a cross-sectional view illustrating a pellicle for extreme ultraviolet lithography according to a first embodiment of the disclosure.

The pellicle for extreme ultraviolet lithography according to the disclosure is constituted by a support part 100 and a pellicle part 200. The pellicle part 200 is placed on the support part 100, and the support part 100 functions to support the pellicle part 200.

The support part 100 includes a support layer pattern 110a and an etch stop layer pattern 120a. The support part 100 may also include a reinforcing layer pattern 210a, and as will be described later, the reinforcing layer pattern 210a may be removed as necessary.

As will be described later, the support layer pattern 110a is formed by etching a support layer 110 and the etch stop layer pattern 120a is formed by etching an etch stop layer 120. When forming the support layer pattern 110a through wet etching, an edge of an etching area may be etched faster than a central area. Accordingly, as an edge of the pellicle part 200 is exposed first, an edge area of the pellicle part 200 may be excessively etched and destroyed before the formation of the support layer pattern 110a is completed. In order to solve this problem and accurately control a thickness of a thin film, the etch stop layer 120 is formed in the disclosure.

The support layer pattern 110a is made of a material having an excellent etch selectivity for the etch stop layer 120, and specifically, may be made of at least one material of silicon, chromium (Cr), titanium (Ti), molybdenum (Mo), nickel (Ni), tungsten (W) including at least one of single crystal, amorphous, and polycrystalline states or a compound in which the at least one material contains at least one of oxygen (O), nitrogen (N), and carbon (C). The support layer pattern 110a has a thickness of 1 μm or less, and preferably 50 to 200 nm.

The pellicle part 200 includes a reinforcing layer 210 and a center layer 220.

The center layer 220 functions to transmit extreme ultraviolet, and is made of a material having excellent heat radiation capability so that heat energy accumulated in the pellicle part 200 may be released to the outside by EUV having high energy. Specifically, the center layer 220 is made of silicon (Si), and also contains at least one material of zirconium (Zr), zinc (Zn), ruthenium (Ru), and molybdenum (Mo). In addition, the center layer 220 may be made of a compound in which the at least one material contains at least one of nitrogen (N), carbon (C), and oxygen (O). The silicon contained in the center layer 220 functions to secure the transmittance required for the pellicle. The metal material contained in the center layer 220 functions to improve the thermal properties of the center layer 220.

The center layer 220 has a thickness of 100 nm or less, and preferably 10 to 30 nm. When the transmittance required for the pellicle part 200 is 90% or more, the center layer 220 may have a thickness of 10 nm as thin as possible, and when the required transmittance is 80% or more, the center layer 220 may have a thickness of 30 nm. The center layer 220 may be formed in a single layer or a multilayer.

The center layer 220 may be surface-treated through ion implantation or diffusion process using ions or gases of one or more materials of phosphorus (P), boron (B), arsenic (As), antimony (Sb), nitrogen (N), carbon (C), oxygen (O), and hydrogen (H) to improve thermal, mechanical, and chemical properties.

The reinforcing layer 210 functions to improve the mechanical strength and secure the chemical stability of the center layer 220 while maintaining a high transmittance to the EUV exposure light. The reinforcing layer 210 may be made of a material containing at least one of silicon (Si), boron (B), zirconium (Zr), nitrogen (N), carbon (C), and oxygen (O). As an example, the reinforcing layer 210 may be made of SiC, SiN, SiO₂, B₄C, BN, and ZrN. These materials have a low reaction with hydrogen (H) radicals present in the environment in which the pellicle is used, thereby securing the chemical stability and also securing the mechanical stability.

The reinforcing layer 210 has a thickness of 50 nm or less, and preferably 2 to 5 nm. When the thickness is 2 nm or less, the function of the reinforcing layer 210 is not exhibited, and when the thickness is 5 nm or more, it is difficult to secure the minimum transmittance required for the pellicle part 200, for example, 80% or more. The reinforcing layer 210 may be formed in a single layer or a multilayer.

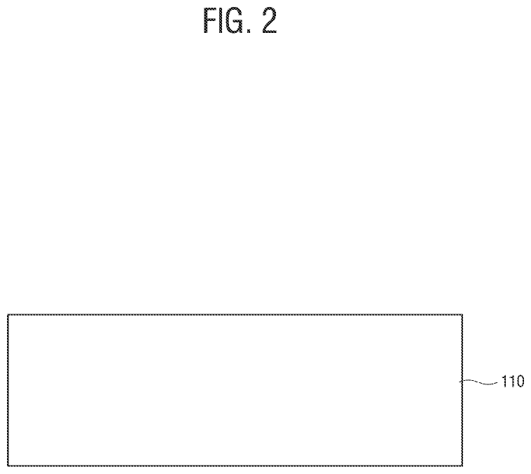

FIGS. 2 to 8 are diagrams sequentially illustrating a manufacturing process of the pellicle for extreme ultraviolet lithography of FIG. 1.

Referring to FIG. 2, a silicon or quartz wafer substrate is prepared as the support layer 110 used as a basis for manufacturing the pellicle for extreme ultraviolet lithography according to the disclosure.

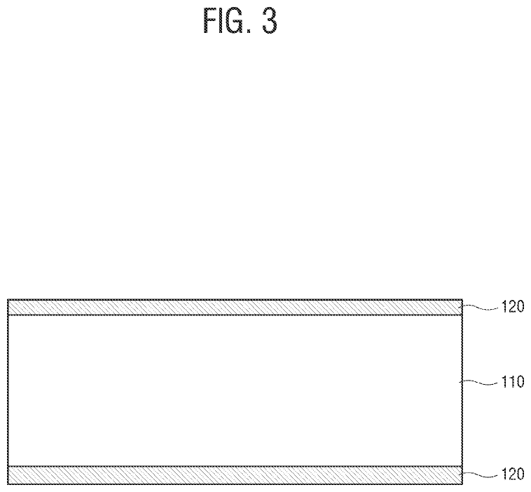

Referring to FIG. 3, the etch stop layer 120 is formed on the support layer 110. The etch stop layer 120 is formed by methods such as thermal oxidation, chemical vapor deposition (CVD), plasma enhanced chemical vapor deposition, sputtering, atomic layer deposition, and ion beam deposition. As the etch stop layer 120 is formed by deposition, the etch stop layer 120 is formed on both surfaces of the support layer 110, that is, on both upper and lower surfaces.

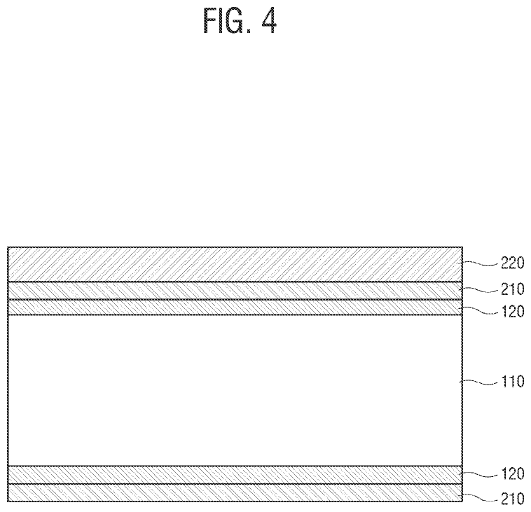

Referring to FIG. 4, a reinforcing layer 210 and a center layer 220 are sequentially formed on the etch stop layer 120. The reinforcing layer 210 is formed on outer surfaces of upper and lower etch stop layers 120, respectively. The reinforcing layer 210 and the center layer 220 are formed by methods such as chemical vapor deposition (CVD), sputtering, E-beam deposition, atomic layer deposition, and ion beam deposition. After the center layer 220 is deposited, the center layer 220 is surface-treated through ion implantation or diffusion process using ions or gases of one or more materials of phosphorus (P), boron (B), arsenic (As), antimony (Sb), nitrogen (N), carbon (C), oxygen (O), and hydrogen (H).

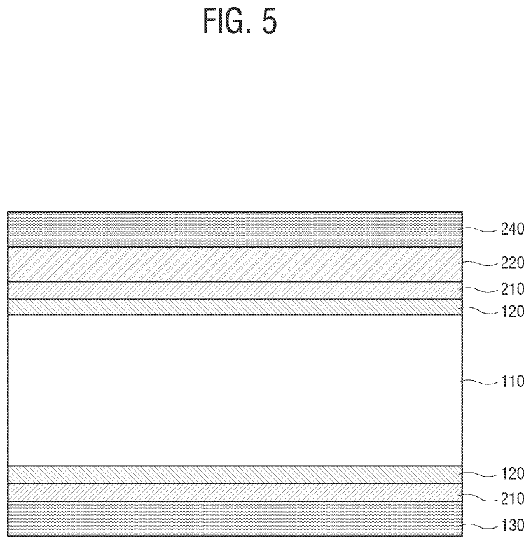

Referring to FIG. 5, an upper etch mask layer 240 is formed on the center layer 220 and the same material as the upper etch mask layer 240 is deposited under the support layer 110 to form a lower etch mask layer 130. The upper etch mask layer 240 and the lower etch mask layer 130 may be formed simultaneously in one process.

The upper etch mask layer 240 functions to protect the pellicle part 200 from an etching solution when the support layer 110 is etched to form the support layer pattern 110a. To this end, the upper etch mask layer 240 is made of a material having an excellent etch selectivity with respect to the etch solution of the support layer 110. The upper etch mask layer 240 may be made of at least one material of silicon, chromium (Cr), titanium (Ti), molybdenum (Mo), nickel (Ni), and tungsten (W) including one or more of single crystal, amorphous, and polycrystalline states or a compound in which the at least one material contains at least one of oxygen (O), nitrogen (N), and carbon (C). It is preferable that the upper etch mask layer 240 has a thickness of 1 μm or less. The lower etch mask layer 130 may be configured to have the same or similar composition and thickness as the upper etch mask layer 240.

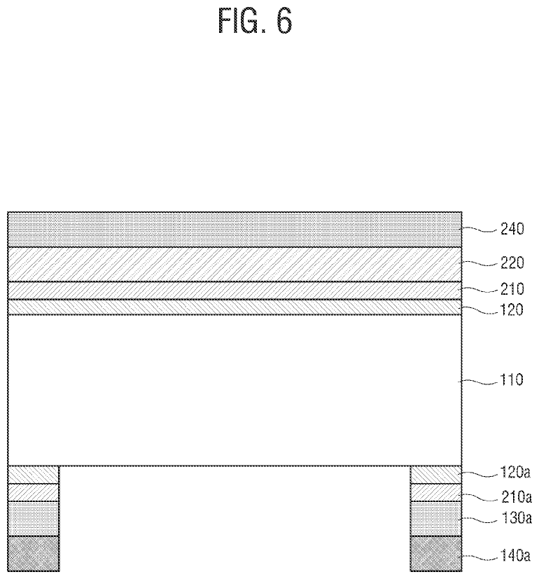

Referring to FIG. 6, a photoresist film is formed on the lower etch mask layer 130 and then patterned to form a resist pattern 140a. Thereafter, the lower etch mask layer 130 is patterned by dry or wet etching using the resist pattern 140a as the etch mask to form a lower etch mask layer pattern 130a that exposes a part of the lower reinforcing layer 210. Then, the lower reinforcing layer 210 and the lower etch stop layer 120 are etched using the resist pattern 140a and the lower etch mask layer pattern 130a as the etch mask to form the reinforcing layer pattern 210a and the lower etch stop layer pattern 120a.

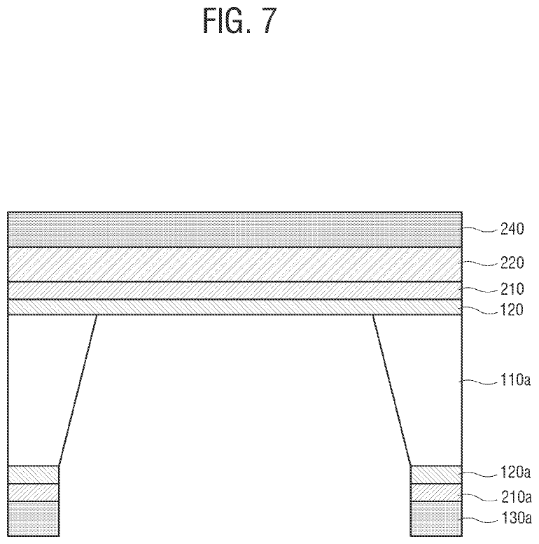

Referring to FIG. 7, after the resist pattern 140a is removed, the support layer 110 is etched by dry etching or a wet etching process using solutions such as KOH, TMAH, and EDP by using the lower etch mask layer pattern 130a, the reinforcing layer pattern 210a, and the lower etch stop layer pattern 120a as the etching mask. Accordingly, the support layer pattern 110a exposing the etch stop layer 120 on the support layer 110 is formed. In the dry etching, isotropic etching or anisotropic etching may be combined.

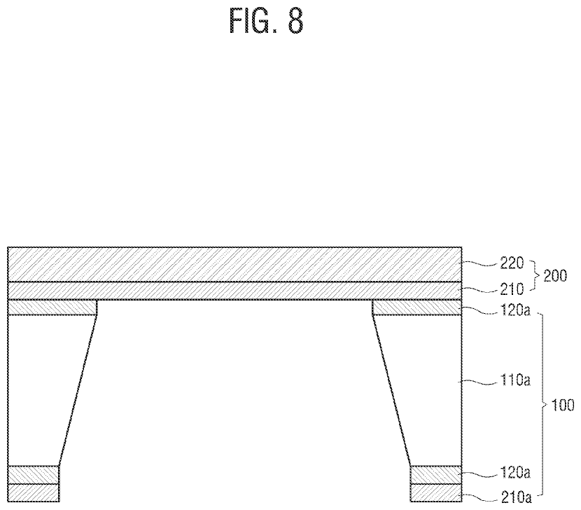

Referring to FIG. 8, the upper etch stop layer pattern 120a exposing the pellicle part 200 is formed on the support layer pattern 110a by removing the upper etch mask layer 240 and the lower etch mask layer pattern 130a and etching the etch stop layer 120. As a result, the manufacture of the pellicle is completed. The reinforcing layer pattern 210a and the etch stop layer pattern 120a under the support layer pattern 110a may be removed as necessary or may remain unremoved.

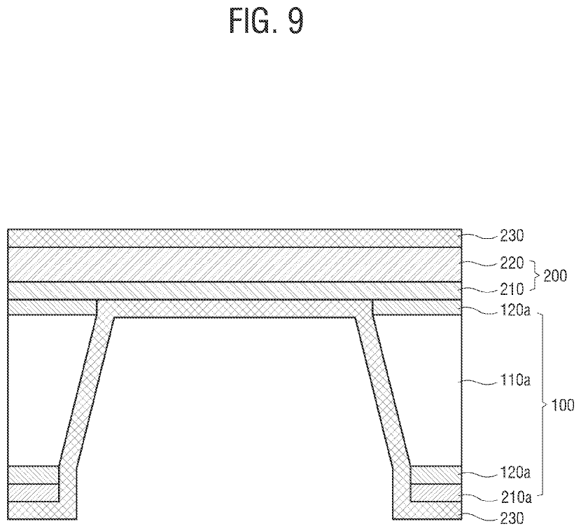

FIG. 9 is a cross-sectional view illustrating a pellicle for extreme ultraviolet lithography according to a second embodiment of the disclosure.

In this embodiment, the pellicle part 200 additionally includes a capping layer 230 in addition to the components of the first embodiment. In the state of FIG. 1, a pellicle having a structure as illustrated in FIG. 9 may be manufactured by additionally forming the capping layer 230 covering the center layer 220 and the reinforcing layer 210 on upper and lower portions of the pellicle part 200, respectively. The capping layer 230 may be formed only on one of the upper and lower portions of the pellicle part 200, and each capping layer 230 may have a single layer structure or a multilayer structure of two or more layers. In the case of the capping layer 230 on the pellicle part 200, the capping layer 230 may be formed before the process of FIG. 5 is performed in the state of FIG. 4, that is, before the upper etch mask layer 240 is formed. In the case of the capping layer 230 under the pellicle part 200, the capping layer 230 may be formed in the state of FIG. 8. The capping layer 230 functions to improve mechanical properties of the pellicle part 200 and improve chemical stability.

The capping layer may be made of at least one material of silicon (Si), boron (B), zirconium (Zr), zinc (Zn), niobium (Nb), or titanium (Ti), or may be made of a compound in which the at least one material or these materials contain at least one material of nitrogen (N), carbon (C), and oxygen (O). The capping layer 230 has a thickness of 50 nm or less, and preferably 2 to 5 nm.

Hereinabove, the disclosure has been specifically described through the structure of the disclosure with reference to the accompanying drawings, but this structure is only used for the purpose of illustrating and explaining the disclosure, and is not used to limit the meaning or the scope of the disclosure described in the claims. Therefore, those having ordinary skill in the technical field of the disclosure can understand that various modifications and equivalent other structures are possible from the structure. Accordingly, an actual technical scope of the disclosure is to be defined by the spirit of the appended claims.

What is claimed is:

1. A pellicle for extreme ultraviolet lithography, comprising:
a pellicle part configured to include a center layer and a reinforcing layer,
wherein the center layer essentially contains silicon (Si), and additionally contains at least one material of zirconium (Zr), zinc (Zn), ruthenium (Ru), and molybdenum (Mo), or is made of a compound which additionally contains at least one of nitrogen (N), carbon (C), and oxygen (O) added to the at least one material, and
the reinforcing layer is made of a material containing at least one of silicon (Si), boron (B), zirconium (Zr), nitrogen (N), carbon (C), and oxygen (O).

2. The pellicle for extreme ultraviolet lithography of claim 1, wherein the center layer has a thickness of 100 nm or less.

3. The pellicle for extreme ultraviolet lithography of claim 1, wherein the central layer is surface-treated through ion implantation or a diffusion process using ion or gas of at least one material of boron (B), arsenic (As), antimony (Sb), nitrogen (N), carbon (C), oxygen (O), and hydrogen (H).

4. The pellicle for extreme ultraviolet lithography of claim 1, wherein the reinforcing layer has a thickness of 50 nm or less.

5. The pellicle for extreme ultraviolet lithography of claim 1, further comprising:
a capping layer having a single layer structure or a multilayer structure which is formed on at least one of upper and lower portions of the center layer.

6. The pellicle for extreme ultraviolet lithography of claim 5, wherein the capping layer is made of at least one material of silicon (Si), boron (B), zirconium (Zr), zinc (Zn), niobium (Nb), titanium (Ti), or nitrogen (N), or is made of a compound which contains at least one material of nitrogen (N), carbon (C), and oxygen (O) added to the at least one material.

7. The pellicle for extreme ultraviolet lithography of claim 6, wherein the capping layer has a thickness of 50 nm or less.
